(19) United States
(12) Patent Application Publication
(10) Pub. No.: US 2009/0219115 A1
(43) Pub. Date: Sep. 3, 2009

(54) Resonant Element and Method for Manufacturing the Same

(75) Inventors: Tatsuya Tujiguchi, Ishikawa-ken (JP); Yasunori Takei, Komatsu-shi (JP); Nobuyoshi Honda, Kanazawa-shi (JP)

Correspondence Address: DICKSTEIN SHAPIRO LLP, 1177 AVENUE OF THE AMERICAS (6TH AVENUE), NEW YORK, NY, 10036-2714, US

(73) Assignee: Murata Manufacturing Co., Ltd.

(21) Appl. No.: 12/465,955

(22) Filed: May 14, 2009

Related U.S. Application Data
(63) Continuation of application No. PCT/JP2007/071964, filed on Nov. 13, 2007.

(30) Foreign Application Priority Data
Feb. 1, 2007 (JP) 2007-023461

(51) Int. Cl. H01P 3/08; H05K 3/10

(52) U.S. Cl. 333/204; 29/846

(57) ABSTRACT

A plurality of flat-plate filter elements are placed on a pallet having a plurality of holding holes. Each of the filter elements includes a rear-principal-surface electrode pattern having a ground electrode provided on a rear principal surface and a front-principal-surface electrode pattern having a principal-surface electrode provided on a front principal surface. One of a first side surface and a second side surface of each of the filter elements is placed on a printing surface of the pallet. A first side-surface electrode pattern of a point-symmetric form in the side surfaces is formed on the side surfaces placed on the printing surface of the pallet. Then, the filter elements are vertically inverted, and a second side-surface electrode pattern having the same form as the first side-surface electrode pattern is formed on the side surfaces facing each other.

### CROSS REFERENCE TO RELATED APPLICATIONS

The present application is a continuation of International Application No. PCT/JP2007/071964, filed Nov. 13, 2007, which claims priority to Japanese Patent Application No. JP2007-023461, filed Feb. 1, 2007, the entire contents of each of these applications being incorporated herein by reference in their entirety.

### FIELD OF THE INVENTION

The present invention relates to a resonant element including quarter-wavelength stripline resonators provided on a dielectric substrate, and to a method for manufacturing the resonant element.

### BACKGROUND OF THE INVENTION

A resonant element, such as a filter or a balun, including stripline resonators provided on a dielectric substrate has been used (e.g., see Patent Document 1).

Now, a configuration of a conventional resonant element is described by using a filter as an example. FIG. 1 is a developed view of a conventional filter.

A resonant element 101 is constituted through interdigital coupling of five stages of stripline resonators, each functioning as a quarter-wavelength resonator. A ground electrode 103 and terminal electrodes 104A and 104B are provided on a rear principal surface 102A of a dielectric substrate 102. Principal-surface electrodes 105A to 105E are provided on a front principal surface 102B. Short-circuit electrodes 106A to 106E and lead electrodes 107A and 107B are provided on side surfaces 102C and 102D.

The principal-surface electrodes 105A to 150E connect to the ground electrode 103 via the short-circuit electrodes 106A to 106E, respectively. The principal-surface electrodes 105A, 105C, and 105E are parallel to each other, extend from an edge side of the side surface 102C toward the side surface 102D, and have short-circuit ends at the edges on the side surface 102C side and open ends at the edges on the side surface 102D side. The principal-surface electrodes 105B and 105D are parallel to each other, extend from an edge side of the side surface 102D toward the side surface 102C, and have short-circuit ends at the edges on the side surface 102D side and open ends at the edges on the side surface 102C side.

Also, the open ends of the principal-surface electrodes 105A and 105E constituting the resonators in the first and last stages connect to the terminal electrodes 104A and 104B on the rear principal surface 102A via the lead electrodes 107A and 107B on the side surface 102D. Accordingly, the resonant element 101 obtains very strong external coupling. In addition, a plurality of glass layers (not illustrated) are laminated on the front principal surface 102B of the dielectric substrate 102.

Patent Document 1: Japanese Unexamined Patent Application Publication No. 2001-358501

In the resonant element having the above-described configuration, the positions of the short-circuit ends of the principal-surface electrodes constituting the resonators do not match on the side surfaces facing each other, and the positions of the side-surface electrodes are different on the respective side surfaces.

Therefore, when side-surface electrode patterns of a plurality of resonant elements are simultaneously printed during manufacturing of the resonant elements, the respective elements need to be aligned on a pallet with the orientations of the respective surfaces of the elements being the same before printing. This process is sophisticated, e.g., the process is performed with the use of an aligning apparatus to recognize and correct respective orientations of a plurality of elements by using an image recognizing technique, thereby increasing the manufacturing cost.

Furthermore, when such a resonant element is mounted on a substrate, the amounts of solder on the respective side surfaces are uneven due to asymmetry of the positions of the side-surface electrodes. Accordingly, the tension applied to the resonant element from molten solder differs on the respective side surfaces, so that a mount position may be displaced from an appropriate mount position.

### SUMMARY OF THE INVENTION

Accordingly, an object of the present invention is to provide a method for manufacturing resonant elements in a simplified process of aligning a plurality of resonant elements and to provide resonant elements that can be manufactured by the method and that are capable of reducing displacement at mounting.

In respective resonant elements, first and second side-surface electrode patterns have the same form, whereby those side-surface electrode patterns can be formed in similar processes, for example, in a process using the same metal mask or screen mask. Therefore, side-surface electrode patterns of a plurality of resonant elements can be printed at one time even if any of the first and second side surfaces is placed on a printing surface. Accordingly, the manufacturing cost can be suppressed. Also, when the resonant element is mounted on a mounting substrate, asymmetry in amounts of solder welded to the side-surface electrode patterns can be prevented. Thus, this configuration reduces the risk of displacement of a mount position of the resonant element due to a difference in tensions of molten solder in a reflow process or the like, so that connection failure or characteristic failure is less likely to occur.

The first and second side-surface electrode patterns of the resonant element may be formed symmetrically in the respective side surfaces. In this configuration, asymmetry in amounts of solder welded to the side-surface electrode patterns can be further prevented when the resonant element is mounted on the mounting substrate. Thus, this configuration further reduces the risk of displacement of a mount position of the resonant element due to a difference in tensions of molten solder in a reflow process or the like, so that connection failure or characteristic failure is less likely to occur.

The first and second side-surface electrode patterns may be provided with a plurality of side-surface electrodes that are in conduction with the same principal-surface electrode. In this configuration, it is easy to place the respective side-surface electrode patterns in a point-symmetric manner and to form the side-surface electrode patterns that match each other on the side surfaces facing each other. Also, if there are other adjacent side-surface electrodes on the outer side of the above-described plurality of side-surface electrodes, electromagnetic-field coupling occurs between the plurality of side-surface electrodes and the other side-surface electrodes. Thus, in this configuration, the frequency characteristic can be easily adjusted by causing a significant change in electromagnetic-field coupling, particularly multipath coupling, through adjustment of gaps between those side-surface electrodes.

The principal-surface electrode that is in conduction with the plurality of side-surface electrodes may have a wide end portion that is in conduction with the plurality of side-surface electrodes. With this configuration, even if a cut error occurs at cutting of a mother substrate into dielectric substrates, no influence is exerted on a narrow portion of the principal-surface electrode and thus an influence on the resonator length reduces.

Dummy electrodes separated from the principal-surface electrode constituting part of the resonators may be provided in the first and second side-surface electrode patterns. In this configuration, the dummy electrodes easily enable formation of point-symmetric side-surface electrode patterns and side-surface electrode patterns that match each other on the side surfaces facing each other. If the position where the dummy electrodes are formed is close to the principal-surface electrode constituting the resonators, end capacitance is added to the principal-surface electrode. Thus, in this configuration, the frequency characteristic can be easily adjusted by causing a significant change in end capacitance through adjustment of gaps between the dummy electrodes and the principal-surface electrode.

As the principal-surface electrode pattern, an end capacitance electrode that continues to the dummy electrodes and that causes end capacitance to be generated in the principal-surface electrode constituting the resonators may be provided. In this configuration, the gap between the end capacitance electrode and the principal-surface electrode is constant even if a cut error occurs at cutting of a mother substrate into dielectric substrates. Therefore, variations in end capacitance can be reduced and an influence of the cut error exerted on the resonance characteristic can be reduced.

A side-surface electrode pattern that is point-symmetric in the side surface is formed on side surfaces placed on a printing surface of a pallet of dielectric substrates placed in holding holes of the pallet, and a side-surface electrode pattern having the same form is formed on the facing side surface, whereby resonant elements are manufactured. Accordingly, side-surface electrode patterns can be formed on the two side surfaces facing each other by using the same printing pattern, so that the process of aligning the resonant elements can be simplified.

According to the present invention, a process of aligning a plurality of resonant elements before forming of side surface electrodes is simplified. Accordingly, the manufacturing cost can be suppressed. Also, the risk of displacement of positions where resonant elements are mounted during a mounting process can be reduced, so that connection failure or characteristic failure can be suppressed.

### BRIEF DESCRIPTION OF DRAWINGS

FIG. 1 is a diagram illustrating a conventional configuration of a resonant element.

FIGS. 2(A) to 2(D) are developed views illustrating a configuration example of a resonant element according to the present invention.

FIGS. 3(A) and 3(B) are graphs for comparison of frequency characteristics of the configuration example according to the present invention and the conventional configuration.

FIG. 4 is a flowchart illustrating a manufacturing process of the configuration example according to the present invention.

FIGS. 5(A) and 5(b) are diagrams illustrating printing of the configuration example according to the present invention.

FIGS. 6(A) to 6(D) are developed views illustrating another configuration example of the resonant element according to the present invention.

FIGS. 7(A) to 7(G) are developed views illustrating another configuration example of the resonant element according to the present invention.

### REFERENCE NUMERALS

1: filter element

2, 12, and 22: dielectric substrate

2A, 2B, 12A, 12B, 22A, and 22B: principal surface

2C, 2D, 2E, 2F, 12C, 12D, 12E, 12F, 22C, 22D, 22E, and

22F: side surface

3, 13, and 23: ground electrode

4, 14, and 24: terminal electrode

5, 15, and 25: principal-surface electrode

6, 16, and 26: short-circuit electrode

7, 17, and 27: lead electrode

18 and 28: dummy electrode

19 and 29: end capacitance electrode

32: glass layer

33: skip coupling electrode

50: pallet

51: holding hole

52: chamfered portion

53: printing surface

### DETAILED DESCRIPTION OF THE INVENTION

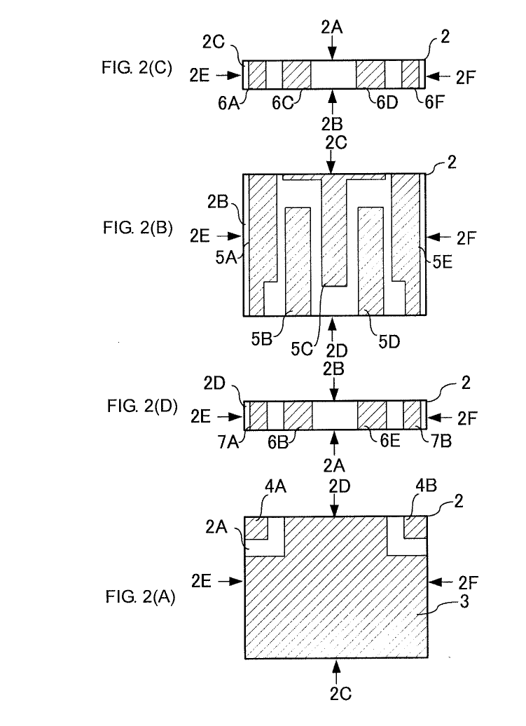

Hereinafter, the present invention is described on the basis of configuration examples of a resonant element. FIGS. 2(A)-2(D) are partial developed views of a resonant element. This resonant element includes stripline resonators and is used as a filter that is used for UWB (Ultra Wide Band) communication of high frequencies in a wide band.

This resonant element includes a dielectric substrate 2 having a compact rectangular parallelepiped shape. The dielectric substrate 2 is made of a ceramic dielectric material, such as titanium oxide. The dielectric substrate 2 has a relative permittivity of about 110, a thickness of 500 μm, a dimension in a lateral direction in the figures of about 3.2 mm, and a dimension in a short-side direction of principal surfaces of about 2.5 mm.

The composition and dimensions of the dielectric substrate 2 may be appropriately set in view of a frequency characteristic and so on.

A rear principal surface 2A of the dielectric substrate 2 illustrated in FIG. 2(A) is a mount surface of this resonant element and is provided with a ground electrode 3 and terminal electrodes 4A and 4B as a rear-principal-surface electrode pattern. The ground electrode 3 serves as a ground electrode of resonators and is provided on almost the entire rear principal surface 2A of the dielectric substrate 2. The terminal electrodes 4A and 4B are placed near both corners contacting a side surface 2D, while being separated from the ground electrode 3. The terminal electrodes 4A and 4B are connected to a high-frequency-signal input/output terminal when the filter element is mounted on a mounting substrate. The respective electrodes constituting the rear-principal-surface electrode pattern have a thickness of about 12 μm and are formed by screen printing or metal mask printing with a silver electrode paste.

A plurality of principal-surface electrodes 5A to 5E are provided as a front-principal-surface electrode pattern on a front principal surface 2B of the dielectric substrate 2 illustrated in FIG. 2(B). Any of the principal-surface electrodes 5A to 5E is a substantially I-shaped silver electrode having a thickness of about 5 μm and is formed by a photolithography process with a photosensitive silver paste with improved electrode precision for the UWB. Those principal-surface electrodes 5A to 5E are portions constituting resonant lines of stripline resonators. The principal-surface electrodes 5A to 5E are parallel to each other. The principal-surface electrodes 5A, 5C, and 5E extend from an edge side as a border of a side surface 2C toward the side surface 2D. The principal-surface electrodes 5B and 5D extend from an edge side as a border of the side surface 2D toward the side surface 2C. On the side of short-circuit ends of the principal-surface electrodes 5A to 5E, the position reaching the side surface 2C or 2D is different on the respective sides of the side surfaces 2C and 2D.

The front principal surface 2B of the dielectric substrate 2 is covered by a glass layer having a thickness of 15 μm or more (not illustrated). This glass layer is formed by printing and firing a glass paste composed of an insulating material, such as crystalline SiO₂ and borosilicate glass, or by a photolithography process and firing using a photosensitive material. The glass layer may be a laminate of a translucent glass layer and a light shielding glass layer. The glass layer mechanically protects the front-principal-surface electrode pattern and increases weather resistance of the filter element. Also, in the case where an electrode is further formed on an upper surface of this glass layer or where an electrode is formed on the front principal surface at printing of side-surface electrodes, short circuit between those electrodes and the front-principal-surface electrode pattern can be prevented. The composition and dimensions of the glass layer may be appropriately set in view of the degree of adhesion between the dielectric substrate 2 and the glass layer, resistance to environment, a frequency characteristic, and so on.

Short-circuit electrodes 6A to 6E and lead electrodes 7A and 7B are provided as a side-surface electrode pattern on the side surfaces 2C and 2D illustrated in FIGS. 2(C) and 2(D). Those electrodes have a thickness of about 12 μm, thicker than the front-principal-surface electrode pattern, and are formed by screen printing or metal mask printing with a silver electrode paste.

Although not illustrated in the figure, no electrode is provided on a right side surface 2F and a left side surface 2E of the dielectric substrate.

The respective principal-surface electrodes 5A to 5E provided on the front principal surface 2B connect to the ground electrode 3 via the short-circuit electrodes 6A to 6E, so as to constitute resonant lines of five stages of quarter-wavelength resonators that couple to each other in an interdigital manner. open ends of the principal-surface electrodes 5A and 5E constituting the resonators in the first and last stages connect to the terminal electrodes 4A and 4B on the rear principal surface 2A via the lead electrodes 7A and 7B on the side surface 2D, so that strong external coupling (tap coupling) is obtained.

The respective principal-surface electrodes 5A and 5E constituting the resonators in the first and fifth stages include a wide portion and a narrow portion. The wide portions connect to the short-circuit electrodes 6A and 6F so as to constitute resonant lines, whereas the narrow portions connect to the lead electrodes 7A and 7B so as to constitute electrodes for tap coupling. The vicinity of the border between the wide portion and the narrow portion serves as an open end of the resonator.

The lead electrodes 7A and 7B have the same width, which is almost the same as the width of the narrow portions of the principal-surface electrodes 5A and 5E. Likewise, the short-circuit electrodes 6A and 6F have the same width, which is almost the same as the width of the narrow portions of the principal-surface electrodes 5A and 5E. In this way, the short-circuit electrodes 6A and 6F are narrow so that the short-circuit electrodes 6A and 6F have the same shape as that of the lead electrodes 7A and 7B. The positions where the short-circuit electrodes 6A and 6F are placed and the positions where the lead electrodes 7A and 7B are placed are point-symmetric in the plane where the respective electrodes are formed. For example, even if the front principal surface 2B and the rear principal surface 2A are inverted or if the side surface 2C and the side surface 2D are inverted, the electrode patterns match each other.

Since the short-circuit electrodes 6A and 6F are narrow, the resonator lengths of the resonators extend and the resonance frequency decreases. In that case, the resonance frequency may be appropriately set by adjusting the position of the border between the wide portion and the narrow portion of the principal-surface electrodes.

The principal-surface electrodes 5B and 5D constituting the resonators in the second and fourth stages have the same width. The short-circuit ends of the principal-surface electrodes 5B and 5D connect to the short-circuit electrodes 6B and 6E on the side surface 2D. Here, the short-circuit electrodes 6B and 6E have the same width, which is almost the same as the width of the principal-surface electrodes 5B and 5D. The positions where the short-circuit electrodes 6B and 6E are placed are point-symmetric in the plane where those electrodes are formed. For example, even if the front principal surface 2B and the rear principal surface 2A are inverted, the electrode patterns match each other.

The principal-surface electrode 5C constituting the resonator in the third stage has a wide portion near the edge side as the border of the side surface 2C. The wide portion connects to the short-circuit electrodes 6C and 6D on the side surface 2C. The principal-surface electrode 5C is short-circuited to the ground electrode 3 via the short-circuit electrodes 6C and 6D. The wide portion of the principal-surface electrode 5C extends from the position where the short-circuit electrode 6C is formed to the short-circuit electrode 6D, and those electrodes constitute a resonator. The wide portion is formed to continue to the two short-circuit electrodes 6C and 6D. If a cut error occurs at cutting of the dielectric substrate, the cut error exerts an influence on the dimension of the line length (short-side direction) of the wide portion, but the cut error does not exert any influence on the dimension of the line length of the narrow portion of the principal-surface electrode 5C. The resonator length of the resonator constituted by the principal-surface electrode 5C is mainly determined by the line length of the narrow portion of the principal-surface electrode 5C. Thus, the influence of the cut error exerted on the resonator length can be reduced by providing the wide portion.

The short-circuit electrodes 6C and 6D have the same width. The positions where the short-circuit electrodes 6C and 6D are placed are point-symmetric in the plane where those electrodes are formed. For example, even if the front principal surface 2B and the rear principal surface 2A are inverted, the electrode patterns match each other. Furthermore, the short-circuit electrodes 6C and 6D have the same width as that of the short-circuit electrodes 6B and 6E provided on the facing side surface 2D, and the positions thereof match each other. For example even if the side surface 2C and the side surface 2D are inverted, the electrode patterns match each other.

A side-surface electrode pattern including the short-circuit electrodes 6A, 6C, 6D, and 6F provided on the side surface 2C and a side-surface electrode pattern including the short-circuit electrodes 6B and 6E and the lead electrodes 7A and 7B provided on the side surface 2D match each other and are point-symmetric in the planes where the respective patterns are formed. Thus, an electrode formation area on the side surface 2D is equal to an electrode formation area on the side surface 2C. Therefore, when the filter element is mounted on the mounting substrate, the amounts of solder used to solder the side-surface electrodes on the side surfaces 2C and 2D are substantially equal to each other. In that case, the tensions of molten solder on the side surfaces 2C and 2D are equal to each other, so that displacement of the filter element on the mounting substrate during soldering hardly occurs.

Depending on setting of the shape of the principal-surface electrode 5C, the vicinity of the border between the wide portion and the narrow portion operates as a short-circuit end of the resonator. Also, multipath coupling occurs between the short-circuit electrodes 6C and 6D and the short-circuit electrodes 6A and 6F adjacent thereto. In this way, the multipath coupling is added to the short-circuit ends of the resonators, and thus the strength of inductive coupling between the resonators in the first and third stages and between the resonators in the third and fifth stages increases. Incidentally, the degree of multipath coupling is determined by the gap between the short-circuit electrodes 6C and 6A and the gap between the short-circuit electrodes 6D and 6F.

The side-surface electrode patterns are thicker than the front-principal-surface electrode pattern, and thus the current in the part on the short-circuit end side where current concentration typically occurs is distributed so as to reduce conductor loss. With this configuration, this resonant element has a small insertion loss.

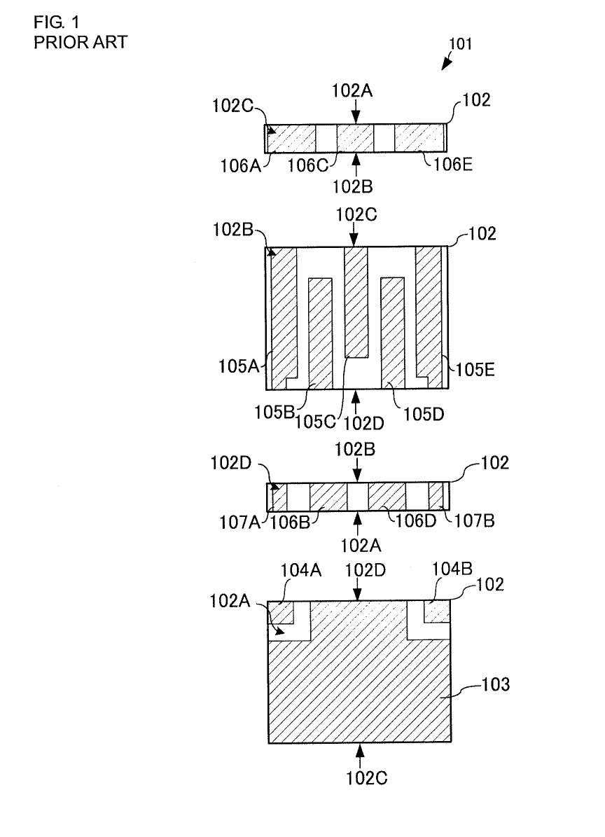

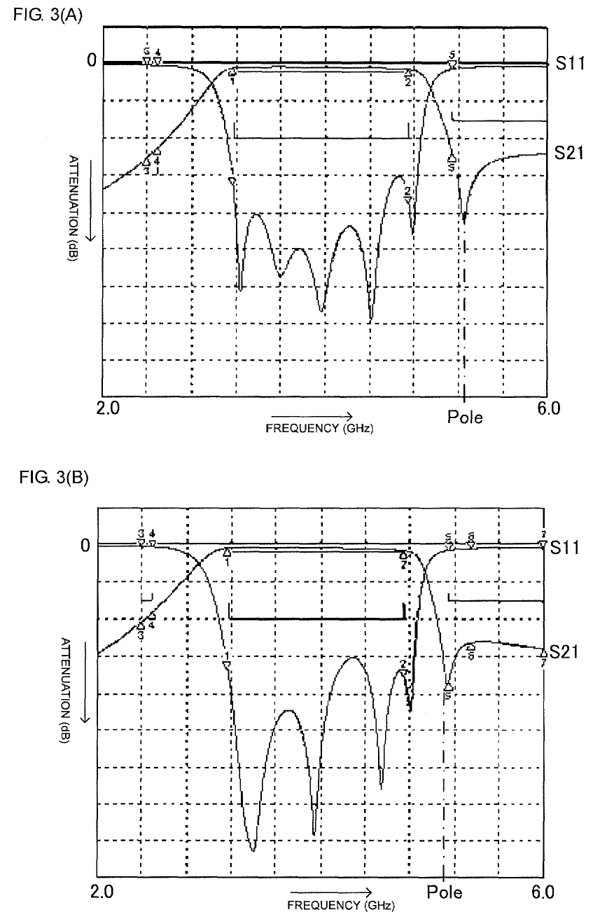

Now, a difference in electrical characteristic between the filter element of this configuration and a filter element of a conventional configuration is described. FIG. 3(A) illustrates a filter characteristic of the filter element of the conventional configuration illustrated in FIG. 1, whereas FIG. 3(B) illustrates a filter characteristic of the filter element of the present invention shown in FIGS. 2(A) to 2(D).

The present invention is different from the conventional configuration in that the resonators in the first and third stages and the resonators in the third and fifth stages couple to each other by skipping a resonator. In this configuration, multipath coupling is allowed to occur, so that an attenuation pole on the wideband side of the filter approaches the band, at about 5.9 GHz, as illustrated in FIG. 3(B). Compared to the conventional configuration illustrated in FIG. 3(A), in which the attenuation pole is at about 6.1 GHz, an improved filter characteristic is obtained.

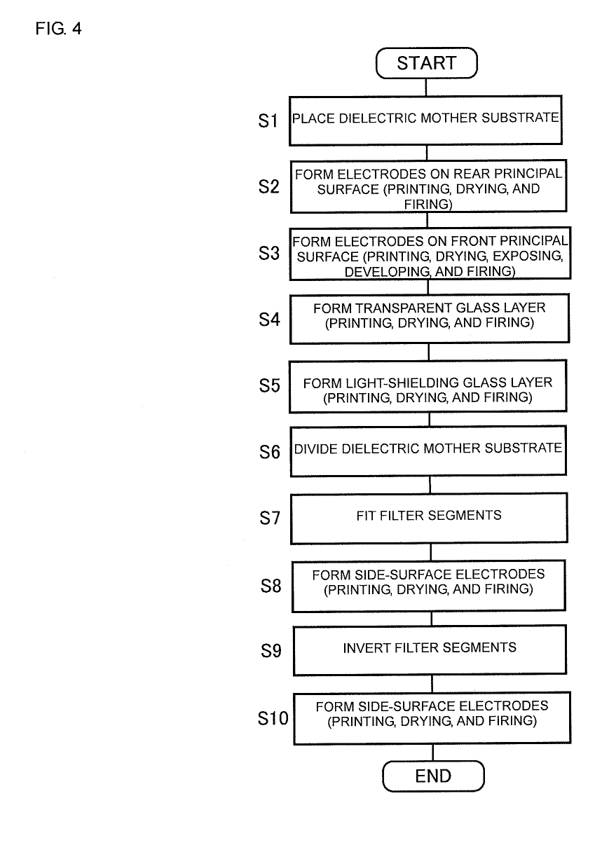

The filter element having the above-described configuration is manufactured through the process illustrated in FIG. 4.

(S1) First, a dielectric mother substrate having no electrode on any surface is prepared.

(S2) Then, screen printing or metal mask printing is performed with a conductive paste on a rear principal surface of the mother substrate, and a ground electrode and a terminal electrode are formed through firing.

(S3) Then, printing is performed with a photosensitive conductive paste on a front principal surface of the mother substrate, and respective principal-surface electrodes are formed through firing after a photolithography process including exposure and development.

(S4) Then, printing is performed with a glass paste on the front principal surface of the mother substrate and a transparent glass layer is formed through firing.

(S5) Then, printing is performed with a glass paste containing an inorganic pigment on the front principal surface of the mother substrate, and a light-shielding glass layer is formed through firing.

(S6) Then, many segments are obtained through dicing or the like from the mother substrate constituted in the above-described manner. After the dicing, preliminary measurement of an electrical characteristic is performed on an upper-surface pattern of part of the segments.

(S7) Then, the respective segments are fit into holding holes of a printing pallet such that the side surfaces 2C or the side surfaces 2D of the respective segments are placed on a printing surface of the printing pallet.

(S8) Printing with a conductive paste is performed on the segments on the printing pallet by using a metal mask or a screen mask having a predetermined pattern so as to form a side-surface electrode pattern, and firing is performed.

(S9) Then, the respective elements are inverted while being aligned so as to place the side surfaces 2D or the side surfaces 2C of the respective segments on the printing surface of the printing pallet.

(S10) Printing with a conductive paste is performed on the segments on the printing pallet by using the above-described metal mask or screen mask so as to form the same side-surface electrode pattern as that described above, and filter elements are manufactured through firing.

Now, placement of the segments in the holding holes of the printing pallet is described.

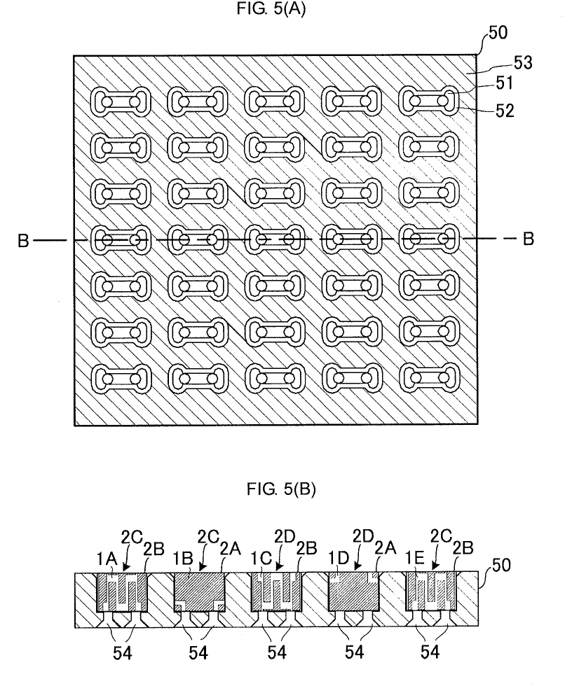

In this embodiment, a placing pallet and a printing pallet are used in order to place the side surfaces 2C or the side surfaces 2D of the filter elements (segments) 1 having a compact rectangular parallelepiped shape on a printing surface 53 of the printing pallet. An example of a representative form of the pallet is illustrated in FIG. 5(A). The pallet is held by a vibrating mechanism (not illustrated) so that the pallet can vibrate.

The pallet 50 is a member to align a plurality of filter elements and includes the printing surface 53 provided with a plurality of holding holes 51. A chamfered portion 52 is provided at the edge of the respective holding holes 51. Also, pushing holes 54 for pushing out the fit filter element 1 are provided at a bottom surface of the respective holding holes 51. The opening size on the printing surface 53 of the holding hole 51 is substantially equal to the size of the side surface 2C and the side surface 2D in the printing pallet. Also, the opening size is substantially equal to the size of the side surface 2E and the side surface 2F in the placing pallet.

In the configuration according to this embodiment, the size of the side surface 2C and the side surface 2D is larger than the size of the side surface 2E and the side surface 2F. Thus, the placing pallet provided with a plurality of holding holes having almost the same dimension as that of the side surface 2E and the side surface 2F is prepared, and a plurality of segments are placed on the placing pallet. Under this state, vibration is given to the placing pallet so as to drop the respective segments into the holding holes. Since the size of each holding hole is almost the same as the size of the side surface 2E and the side surface 2F and is smaller than the size of the side surface 2C and the side surface 2D, the segments dropped into the respective holding holes are reliably placed such that the side surface 2E or the side surface 2F is oriented to the upper side of the placing pallet.

Therefore, the orientation of the side surfaces 2C and the side surfaces 2D can be set to the upper side of the pallet by rotating the respective segments by 90 degrees, with the part between the side surfaces 2A and 2B being the rotation plane. Thus, the printing pallet provided with a plurality of holding holes having the same dimension as that of the side surfaces 2C and 2D is prepared, and the respective segments of which side surfaces 2C and 2D are oriented to the upper side of the pallet by rotation of 90 degrees are placed in the holding holes in the printing pallet.

If the size of the side surface 2C and the side surface 2D is smaller than the size of the side surface 2E and the side surface 2F, the placing pallet is unnecessary. This is because the side surfaces 2C or the side surfaces 2D of the respective segments dropped in the holding holes of the printing pallet are reliably oriented to the upper side of the pallet when the size of the holding holes of the printing pallet is substantially equal to the size of the side surface 2C and the side surface 2D.

FIG. 5(B) is a cross-sectional view taken along the line B-B illustrating an example of the state where the filter elements have been dropped into the holding holes in the printing pallet and a side-surface electrode pattern has been formed on the side surfaces placed on the printing surface.

The filter elements 1 fit in the holding holes 51 on the printing pallet 50 are aligned such that the side surfaces 2C or the side surfaces 2D are oriented in the same direction.

In this state, printing is performed on the side surfaces of the filter elements 1 placed on the printing surface 53 of the pallet 50. The electrode patterns provided on the side surfaces 2C and 2D of the filter elements 1 match each other and have a point-symmetric form. For this reason, the orientations of the respective surfaces of the plurality of filter elements need not perfectly be matched before printing.

When the electrode pattern provided on the side surface 2C matches the electrode pattern provided on the side surface 2D, printing can be performed by simultaneously placing the side surfaces 2C or the side surfaces 2D of the filter elements 1 on the printing surface 53.

When the electrode pattern provided on the side surface 2C and the electrode pattern provided on the side surface 2D are point-symmetric, printing can be performed even if the principal surfaces 2A or the principal surfaces 2B of the filter elements 1 are oriented to the upper or lower side in the figure.

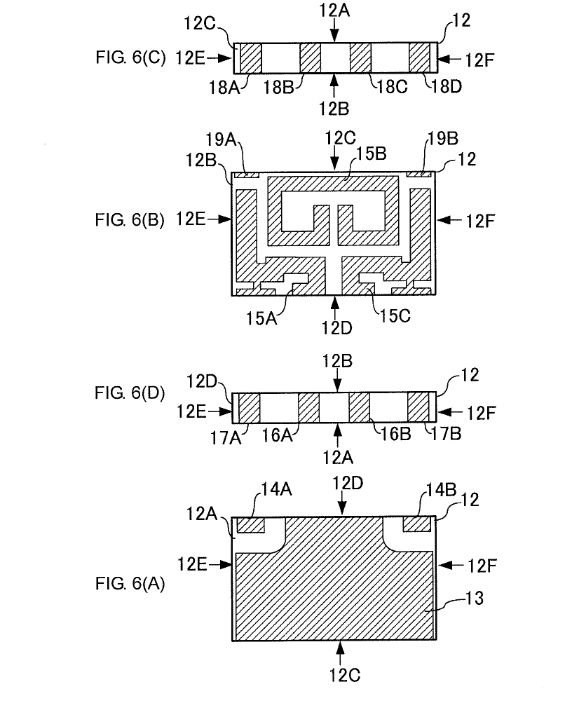

Next, a configuration example of another resonant element is described on the basis of FIGS. 6(A) to 6(D).

This resonant element is a filter element provided with a filter including two quarter-wavelength resonators and one half-wavelength resonator coupled to each other. Hereinafter, explanation about the same configuration as that of the above-described embodiment is omitted in some cases.

This filter element includes a dielectric substrate 12 having a compact rectangular parallelepiped shape. A front principal surface of the dielectric substrate 12 is covered by a glass layer (not illustrated).

A ground electrode 13 and terminal electrodes 14A and 14B are provided as a rear-principal-surface electrode pattern on a rear principal surface 12A of the dielectric substrate 12 illustrates in part (A) of the figure. The ground electrode 13 is provided over almost the entire rear principal surface of the dielectric substrate 12, whereas the terminal electrodes 14A and 14B are placed at the vicinity of both corners contacting a side surface while being separated from the ground electrode 13.

Principal-surface electrodes 15A to 15C and end capacitance electrodes 19A and 19B constituting stripline resonators are provided as a front-principal-surface electrode pattern on a front principal surface 12B of the dielectric substrate 12 illustrated in part (B) of the figure. Any of the principal-surface electrodes 15A to 15C and end capacitance electrodes l9A and 19B is a silver electrode having a thickness of about 5 μm and is formed by a photolithography method using a photosensitive silver paste with an improved electrode precision for high frequencies in a wide band.

Short-circuit electrodes 16A and 16B and lead electrodes 17A and 17B are provided as a side-surface electrode pattern on a side surface 12D illustrated in part (D) of the figure. On the other hand, dummy electrodes 18A to 18D are provided as a side-surface electrode pattern on a side surface 12C illustrated in part (C) of the figure. The respective electrodes constituting the respective side-surface electrode patterns have a thickness of about 12 μm, thicker than the front-principal-surface electrode pattern, and are formed by screen printing or metal mask printing with a silver electrode paste.

Although not illustrated in the figure, no electrode is provided on a right side surface 12F and a left side surface 12E.

The respective principal-surface electrodes 15A and 15C on the front principal surface 12B connect to the ground electrode 13 on the rear principal surface 12A via the short-circuit electrodes 16A and 16B on the side surface 12D, and also connect to the terminal electrodes 14A and 14B on the rear principal surface 12A via the lead electrodes 17A and 17B on the side surface 12D. Also, capacitance is added to the vicinity of the open ends thereof by the end capacitance electrodes 19A and 19B on the front principal surface 12B. The degree of the capacitance is determined by the gap between the end capacitance electrodes 19A and 19B and the principal-surface electrodes 15A and 15C, and the frequency characteristic can be adjusted also by adjusting the gap.

Each of the principal-surface electrodes 15A and 15C is a substantially L-shaped electrode including a portion extending along the side surface 12E or 12F and a portion extending along the side surface 12D, and constitutes a one-end-opened and one-end-short-circuited quarter-wavelength resonator together with the ground electrode 13.

The principal-surface electrodes 15A and 15C continue to the short-circuit electrodes 16A and 16B, respectively, at the vicinity of the center of an edge side as a border of the side surface 12D, and are in conduction with the ground electrode 13 via the short-circuit electrodes 16A and 16B, respectively. Also, in the principal-surface electrode 15A, the portion extending along the side surface 12E continues to the lead electrode 17A at the position contacting the edge side as the boarder of the side surface 12D and is in conduction with the terminal electrode 14A via the lead electrode 17A. Likewise, in the principal-surface electrode 15C, the portion extending along the side surface 12F connects to the lead electrode 17B at the position contacting the edge side as the boarder of the side surface 12D and is in conduction with the terminal electrode 14B via the lead electrode 17B.

The portions extending along the side surface 12D of the principal-surface electrodes 15A and 15C are inflected. The inflection increases the line length of the respective principal-surface electrodes 15A and 15C. The portions extending along the side surface 12D of the principal-surface electrodes 15A and 15C are not necessarily inflected. If the inflection is not provided in the configuration according to this embodiment, the resonator length of the quarter-wavelength resonator can be decreased to increase the resonance frequency. On the other hand, if the inflection is provided to increase the line length, the resonator length of the quarter-wavelength resonator can be increased to decrease the resonance frequency.

Each of the continuous portions between the principal-surface electrodes 15A and 15C and the lead electrodes 17A and 17B includes a wide portion contacting the edge side and a narrow portion extending from the wide portion toward the side surface 12C. The wide portion is provided in order to suppress an influence of a cut error caused during cutting of the dielectric substrate exerted on tap coupling.

The principal-surface electrode 15B is a substantially C-shaped electrode having a closed portion on the side of the side surface 12C and an opened portion on the side of the side surface 12D. The principal-surface electrode 15B has a portion extending along the side surface 12C. Furthermore, the principal-surface electrode 15B has portions that extend from both ends of the portion and that are parallel to the side surfaces 12E and 12F. Furthermore, the principal-surface electrode 15B has portions that extend from the tops of those portions inwardly and that are parallel to the side surface 12D. Furthermore, the principal-surface electrode 15B has portions extending from the tops of those portions toward the side surface 12C. Accordingly, the principal-surface electrode 15B constitutes a half-wavelength resonator whose both ends are opened together with the ground electrode 13. Since the principal-surface electrode 15B is inflected, the resonator length of the half-wavelength resonator can be increased in the limited substrate area.

The line widths of resonant lines constituted by the respective principal-surface electrodes 15A, 15B, and 15C are adjusted to realize a necessary frequency characteristic.

The formation of the above-described principal-surface electrodes 15A to 15C allows the stripline resonator including the principal-surface electrode 15A to couple to the terminal electrode 14A by tap coupling. The two stripline resonators including the principal-surface electrodes 15A and 15B couple to each other in an interdigital manner, and the two stripline resonators including the principal-surface electrodes 15B and 15C couple to each other in an interdigital manner. The stripline resonator including the principal-surface electrode 15C couples to the terminal electrode 14B by tap coupling. Additionally, in the two stripline resonators including the principal-surface electrodes 15A and 15C, the short-circuit end sides are close to each other and multipath coupling occurs.

The lead electrodes 17A and 17B on the side surface 12D have the same width. Also, the short-circuit electrodes 16A and 16B have the same width. Also, the dummy electrodes 18A and 18D on the side surface 12C have the same width, which is the same as the width of the lead electrodes 17A and 17B. Also, the dummy electrodes 18B and 18C on the side surface 12C have the same width, which is the same as the width of the short-circuit electrodes 16A and 16B. Furthermore, the side-surface electrode pattern including the short-circuit electrodes 16A and 16B and the lead electrodes 17A and 17B provided on the side surface 12D and the side-surface electrode pattern including the dummy electrodes 18A to 18D provided on the side surface 12C match each other and are point-symmetric in the planes where the respective patterns are formed. Thus, an electrode formation area on the side surface 12D is equal to an electrode formation area on the side surface 12C.

The respective dummy electrodes 18A to 18D are used only for forming, on the side surface 12C, an electrode pattern that matches the electrode pattern including the short-circuit electrodes 16A and 16B and the lead electrodes 17A and 17B. The dummy electrodes 18A and 18D continue to the end capacitance electrodes 19A and 19B provided on the front principal surface 12B so as to allow the end capacitance electrodes 19A and 19B to be in conduction with the ground electrode 13. Also, the dummy electrodes 18B and 18C are in conduction with the ground electrode 13. Capacitance is added to the resonators constituted by the respective principal-surface electrodes 15A to 15C also by the dummy electrodes 18A to 18D.

In the above-described configuration, too, the side-surface electrode pattern on the side surface 12C and the side-surface electrode pattern on the side surface 12D match each other and are point-symmetric in the planes where the respective patterns are formed, so that the manufacturing thereof is simplified. For example, the manufacturing can be performed by the process and method illustrated in FIGS. 4, 5(A) and 5(B). Accordingly, resonant elements can be inexpensively provided by reducing the manufacturing cost.

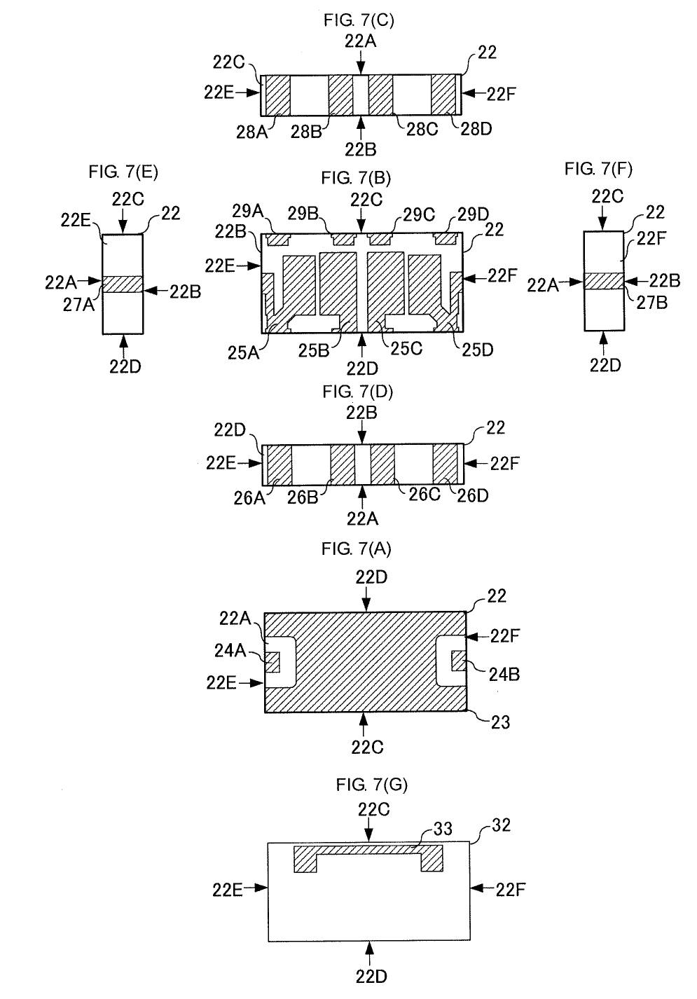

Next, a configuration example of another resonant element is described on the basis of FIGS. 7(A) to 7(G).

This resonant element is a filter element provided with a filter including four quarter-wavelength resonators coupled by comb-line coupling. This filter realizes a narrower-band frequency characteristic due to comb-line coupling compared to the filters according to the above-described other configuration examples. Hereinafter, explanation about the same configuration as that in the above-described embodiment is omitted in some cases.

This filter element includes a dielectric substrate 22 having a compact rectangular parallelepiped shape. The front principal surface side of the dielectric substrate 22 is covered by a glass layer 32.

A ground electrode 23 and terminal electrodes 24A and 24B are provided as a rear-principal-surface electrode pattern on a rear principal surface 22A of the dielectric substrate 22 illustrated in FIG. 7(A). The ground electrode 23 is provided on almost the entire rear principal surface of the dielectric substrate 22, and the terminal electrodes 24A and 24B are placed at the vicinity of the centers of edge sides as borders of side surfaces 22E and 22F, respectively, while being separated from the ground electrode 23.

A plurality of principal-surface electrodes 25A to 25D and end capacitance electrodes 29A to 29D constituting stripline capacitors are provided as a front-principal-surface electrode pattern on a front principal surface 22B of the dielectric substrate 22 illustrated in FIG. 7(B). Any of the principal-surface electrodes 25A to 25D and the end capacitance electrodes 29A to 29D is a silver electrode having a thickness of about 5 μm, and is formed by a photolithography method with a photosensitive silver paste with an improved electrode precision for high frequencies.

Short-circuit electrodes 26A to 26D are provided as a side-surface electrode pattern on a side surface 22D illustrated in FIG. 7(D). Dummy electrodes 28A to 28D are provided as a side-surface electrode pattern on a side surface 22C illustrated in FIG. 7(C). A lead electrode 27A is provided as a side-surface electrode pattern on a side surface 22E illustrated in FIG. 7(E). A lead electrode 27B is provided as a side-surface electrode pattern on a side surface 22F illustrated in FIG. 7(F). Each of the electrodes constituting the respective side-surface electrode patterns has a thickness of about 12 μm, thicker than the front-principal-surface electrode pattern, and is formed by screen printing or metal mask printing with a silver electrode paste.

Also, the glass layer 32 is illustrated in FIG. 7(G). The glass layer 32 is provided with a skip coupling electrode 33 on the front principal surface side. The skip coupling electrode 33 is a silver electrode having a thickness of about 5 μm, and is formed by a photolithography method using a photosensitive silver paste with an improved electrode precision for the UWB.

The respective principal-surface electrodes 25A to 25D on the front principal surface 22B connect to the ground electrode 23 on the rear principal surface 22A via the short-circuit electrodes 26A to 26D on the side surface 22D. Also, the principal-surface electrode 25A connects to the terminal electrode 24A on the rear principal surface 22A via the lead electrode 27A on the side surface 22E, whereas the principal-surface electrode 25D connects to the terminal electrode 24B on the rear principal surface 22A via the lead electrode 27B on the side surface 22F. Furthermore, capacitance is added to the vicinity of the respective open ends of the principal-surface electrodes 25A to 25D by the end capacitance electrodes 29A to 29D on the front principal surface 22B. The degree of the capacitance is determined by the gap between the end capacitance electrodes 29A to 29D and the principal-surface electrodes 25A to 25D, and the frequency characteristic can be adjusted by adjusting the gap.

Each of the principal-surface electrodes 25A and 25D is a substantially U-shaped electrode having a portion extending along the side surface 22E or 22F and a portion extending in parallel with the portion, and constitutes a one-end-opened and one-end-short-circuited quarter-wavelength resonator together with the ground electrode 23. Strong external coupling is obtained by leading the portions extending along the side surfaces 22E and 22F from a middle of resonators and tapping those portions.

The principal-surface electrodes 25A and 25D continue to the short-circuit electrodes 26A and 26D, respectively, at the edge side as the border of the side surface 22D, and are in conduction with the ground electrode 23 via the short-circuit electrodes 26A and 26D, respectively. Also, in the principal-surface electrode 25A, the portion extending along the side surface 22E continues to the lead electrode 27A at the vicinity of the center of the edge side as the border of the side surface 22E, and is in conduction with the terminal electrode 24A via the lead electrode 27A. Likewise, in the principal-surface electrode 25D, the portion extending along the side surface 22F continues to the lead electrode 27B at the vicinity of the center of the edge side as the border of the side surface 22F, and is in conduction with the terminal electrode 24B via the lead electrode 27B.

The continuous portions between the principal-surface electrodes 25A and 25D and the short-circuit electrodes 26A and 26D have a wide portion contacting the edge side and a narrow portion extending from the wide portion toward the side surface 22C. The wide portion is provided to suppress an influence of a cut error that occurs when the dielectric substrate is cut.

The principal-surface electrodes 25B and 25C are I-shaped electrodes extending from the edge side as the border of the side surface 22D toward the side surface 12C, continue to the short-circuit electrodes 26B and 26C, respectively, and are in conduction with the ground electrode 23 via the short-circuit electrodes 26B and 26C, respectively.

The line widths of resonant lines constituted by the respective principal-surface electrodes 25A to 25D are adjusted to realize a necessary frequency characteristic.

Due to the formation of the principal-surface electrodes 25A to 25D, the stripline resonator including the principal-surface electrode 25A couples to the terminal electrode 24A by tap coupling. The two stripline resonators including the principal-surface electrodes 25A and 25B couple to each other by comb-line coupling, the two stripline resonators including the principal-surface electrodes 25B and 25C couple to each other by comb-line coupling, and the two stripline resonators including the principal-surface electrodes 25C and 25D couple to each other by comb-line coupling. The stripline resonator including the principal-surface electrode 25D couples to the terminal electrode 24B by tap coupling.

The short-circuit electrodes 26A and 26D on the side surface 22D have the same width. Also, the short-circuit electrodes 26B and 26C have the same width. Also, the dummy electrodes 28A and 28D on the side surface 22C have the same width, which is the same as the width of the short-circuit electrodes 26A and 26D on the facing side surface 22D. Also, the dummy electrodes 28B and 28C on the side surface 22C have the same width, which is the same as the width of the short-circuit electrodes 26B and 26C on the facing side surface 22D. Furthermore, the side-surface electrode pattern including the short-circuit electrodes 26A to 26D provided on the side surface 22D and the side-surface electrode pattern including the dummy electrodes 28A to 28D provided on the side surface 22C match each other and are point-symmetric in the planes where the respective patterns are formed. Accordingly, an electrode formation area on the side surface 22D can be equal to an electrode formation area on the side surface 22C.

The respective dummy electrodes 28A to 28D are simply provided for forming, on the side surface 22C, the electrode pattern that matches the electrode pattern including the short-circuit electrodes 26A to 26D. The dummy electrodes 28A to 28D cause end capacitance to be added to the open ends of the respective resonators, so that the resonator length reduces and that the filter element can be shortened.

The dummy electrodes 28A to 28D continue to the end capacitance electrodes 29A to 29D provided on the front principal surface 22B and allow the end capacitance electrodes 29A to 29D to be in conduction with the ground electrode 23. Capacitance is added to the resonators constituted by the principal-surface electrodes 25A to 25D also by those dummy electrodes 28A to 28D.

In the above-described configuration, too, the side-surface electrode pattern on the side surface 22C and the side-surface electrode pattern on the side surface 22D match each other and are point-symmetric in the planes where the respective patterns are formed, and manufacturing thereof is simplified. For example, the manufacturing can be performed by the process and method illustrated in FIGS. 4, 5(A) and 5(B). Accordingly, resonant elements can be inexpensively provided by reducing the manufacturing cost.

In addition, the positions of the principal-surface electrodes and the short-circuit electrodes on the side surfaces according to the above-described embodiments are set in accordance with the specifications of products, and any form may be adopted in accordance with the specification of products. The present invention can be applied to a configuration other than the above-described configurations and can be adopted to various pattern forms of filter elements. Furthermore, another configuration (high-frequency circuit) may be placed in this filter element.

1. A resonant element comprising:
a dielectric substrate having opposed first and second principal surfaces, opposed first and second side surfaces, the first and second opposed side surfaces connecting the first and second principal surfaces;
a ground electrode disposed on the first surface of the dielectric substrate;
at least one principal-surface electrode disposed on the second surface of the dielectric substrate;
a first side-surface electrode pattern disposed on the first side surface;
a second side-surface electrode pattern disposed on the second side surface facing the first side surface; and
a signal input/output electrode coupled to at least one of the first or second side-surface electrode patterns,
wherein the first side-surface electrode pattern and the second side-surface electrode pattern match each other.

2. The resonant element according to claim 1, wherein the first side-surface electrode pattern and the second side-surface electrode pattern are symmetric.

3. The resonant element according to claim 1, wherein at least one of the first side-surface electrode pattern and the second side-surface electrode pattern includes a plurality of side-surface electrodes that are in conduction with a mutual principal-surface electrode.

4. The resonant element according to claim 3, wherein the mutual principal-surface electrode that is in conduction with the plurality of side-surface electrodes includes a wide portion and a narrow portion, an end of the mutual principal surface electrode that is in conduction with the plurality of side-surface electrodes being the wide portion.

5. The resonant element according to claim 1, wherein at least one of the first side-surface electrode pattern and the second side-surface electrode pattern includes a dummy electrode separated from the at least one principal-surface electrode.

6. The resonant element according to claim 5, wherein the at least one principal-surface electrode pattern includes an end capacitance electrode that allows the principal-surface electrode constituting at least a part of a resonator to generate end capacitance, and is in conduction with the dummy electrode.

7. The resonant element according to claim 1, wherein the at least one principal surface electrode is substantially I-shaped.

8. The resonant element according to claim 1, wherein the at least one principal surface electrode includes a plurality of principal surface electrodes that are parallel to each other.

9. The resonant element according to claim 1, wherein the at least one principal surface electrode is substantially C-shaped.

10. The resonant element according to claim 1, wherein at least one of the first or second side-surface electrode patterns are thicker than the at least one principal surface electrode.

11. A method of manufacturing a resonant element, the method comprising:
forming a rear-principal-surface electrode pattern including a ground electrode on a rear principal surface of a dielectric substrate;
forming a front-principal-surface electrode pattern including a principal-surface electrode on a front principal surface of the dielectric substrate;
forming a first side-surface electrode pattern on a first side surface of the dielectric substrate, the first side-surface electrode pattern including a side-surface electrode that constitutes a resonator together with the ground electrode and the principal-surface electrode; and
forming a second side-surface electrode pattern on a second side surface facing the first side surface of the dielectric substrate, the second side-surface electrode pattern matching the first side-surface electrode pattern.

12. The method of manufacturing the resonant element according to claim 11, the method further comprising:
placing a plurality of dielectric substrates, each being the said dielectric substrate, in a plurality of holding holes of a pallet so that any of the first and second side surfaces are arranged as a first printing surface;
printing and forming one of the first or second side-surface electrode patterns on the first printing surface; and
printing and forming the other of the first or second side-surface electrode patterns on a second printing surface opposite the first printing surface.
